(19) United States
(12) Patent Application Publication
(10) Pub. No.: US 2026/0086113 A1
(43) Pub. Date: Mar. 26, 2026

(54) APPARATUS AND METHOD FOR TESTING A SEMICONDUCTOR PACKAGE

(71) Applicant: JCET STATS ChipPAC Korea Limited, Incheon (KR)

(72) Inventors: MyungKi KIM, Incheon (KR); JiHyoung YU, Seoul (KR); YoungBeom KIM, Incheon (KR)

(21) Appl. No.: 19/334,995

(22) Filed: Sep. 22, 2025

(30) Foreign Application Priority Data
Sep. 23, 2024 (CN) 202411327509.7

(51) Int. Cl. G01R 1/04; G01R 31/28

(52) U.S. Cl. CPC G01R 1/0466; G01R 31/2863; G01R 31/2896

(57) ABSTRACT

An apparatus for testing a semiconductor package comprises: a test board; an adaptor socket disposed on and electrically coupled to the test board; a first reference module and a second reference module each being removably seated in the reference seat of the adaptor socket; and a test socket disposed on the adaptor socket. The test socket comprises: a socket body having a test seat for seating the semiconductor package, and defining together with the adaptor socket a lower cavity below the test seat and for accommodating the first reference module or the second reference module; and contact pins vertically extending through the socket body between the test seat and the lower cavity and movable vertically relative to the socket body.

### TECHNICAL FIELD

The present application generally relates to semiconductor technology, and more particularly, to an apparatus for testing a semiconductor package and a method for testing a semiconductor package.

### BACKGROUND OF THE INVENTION

The semiconductor industry is constantly faced with complex integration challenges as consumers want their electronics to be smaller, faster and higher performance with more and more functionalities packed into a single device. Semiconductor packages that have undergone complicated processing are subjected to various types of electrical tests so as to test their characteristics and for defects thereof.

To this end, a test socket is used to electrically connect metallic wires or conductive pads of a test board (for example, a printed circuit board) mounted in test equipment and external terminals of a semiconductor package to be tested. That is, when a semiconductor package is being tested, the test socket serves as an interface to electrically connect the test board of the test equipment and the semiconductor package under test.

Therefore, a need exists for a highly convenient and cost-saving apparatus for testing a semiconductor package.

### SUMMARY OF THE INVENTION

An objective of the present application is to provide a highly convenient and cost-saving apparatus for testing a semiconductor package.

According to an aspect of the present application, an apparatus for testing a semiconductor package is provided. The semiconductor package comprises at least a first semiconductor component and a second semiconductor component and a mold cap encapsulating the first and second semiconductor components, wherein the first semiconductor component has a first set of conductive pads exposed from the mold cap, and the second semiconductor component has a second set of conductive pads exposed from the mold cap. The apparatus comprises: a test board; an adaptor socket disposed on and electrically coupled to the test board, wherein the adaptor socket has a reference seat; a first reference module and a second reference module each being removably seated in the reference seat of the adaptor socket so as to be electrically coupled to the test board through the adaptor socket, wherein the first reference module comprises a first base substrate with a first set of test pads and a second reference semiconductor component mounted on the first base substrate in a layout as the second semiconductor component of the semiconductor package, and the second reference module comprises a second base substrate with a second set of test pads and a first reference semiconductor component mounted on the second base substrate in a layout as the first semiconductor component of the semiconductor package; and a test socket disposed on the adaptor socket, wherein the test socket comprises: a socket body having a test seat for seating the semiconductor package, and defining together with the adaptor socket a lower cavity below the test seat and for accommodating the first reference module or the second reference module, such that the first set of test pads of the first reference module are vertically aligned with the first set of conductive pads of the first semiconductor component or the second set of test pads of the second reference module are vertically aligned with the second set of conductive pads of the second semiconductor component when the semiconductor package is seated in the test seat; and contact pins vertically extending through the socket body between the test seat and the lower cavity and movable vertically relative to the socket body, wherein when the semiconductor package is under test, the contact pins are pressed by the semiconductor package against the first reference module or the second reference module to set up an electrical connection between the first set of conductive pads of the first semiconductor component and the first set of test pads of the first reference module or between the second set of conductive pads of the second semiconductor component and the second set of test pads of the second reference module.

In another aspect of the present application, a method for testing a semiconductor package is provided. The semiconductor package comprises at least a first semiconductor component and a second semiconductor component and a mold cap encapsulating the first and second semiconductor components, wherein the first semiconductor component has a first set of conductive pads exposed from the mold cap, and the second semiconductor component has a second set of conductive pads exposed from the mold cap. The method comprises: providing a first reference module and a second reference module, wherein the first reference module comprises a first base substrate with a first set of test pads and a second reference semiconductor component mounted on the first base substrate in a layout as the second semiconductor component of the semiconductor package, and the second reference module comprises a second base substrate with a second set of test pads and a first reference semiconductor component mounted on the second base substrate in a layout as the first semiconductor component of the semiconductor package; providing a test board with an adaptor socket disposed thereon, wherein the adaptor socket is electrically coupled to the test board and has a reference seat; placing the first reference module in the reference seat of the adaptor socket such that the first reference module is electrically coupled to the test board via the adaptor socket; placing a test socket on the adaptor socket, wherein the test socket comprises a socket body having a test seat and defining together with the adaptor socket a lower cavity below the test seat, and contact pins vertically extending through the socket body between test seat and the lower cavity and movable relative to the socket body, and wherein the first reference module is accommodated within the lower cavity; placing the semiconductor package in the test seat of the test socket to set up an electrical connection between the first set of conductive pads of the first semiconductor component and the first set of test pads of the first reference module; removing the semiconductor package, the test socket and the first reference module from the adaptor socket; placing the second reference module in the reference seat of the adaptor socket such that the second reference module is electrically coupled to the test board via the adaptor socket; placing the test socket on the adaptor socket to accommodate the second reference module in the lower cavity; placing the semiconductor package in the test seat of the test socket to set up an electrical connection between the second set of conductive pads of the second semiconductor component and the second set of test pads of the second reference module.

According to another aspect of the present application, an apparatus for testing a semiconductor package is provided. The semiconductor package comprises a plurality of semiconductor components and a mold cap encapsulating the plurality of semiconductor components, wherein each of the plurality of semiconductor components has a set of conductive pads exposed from the mold cap. The apparatus comprises: a test board; an adaptor socket disposed on and electrically coupled to the test board, wherein the adaptor socket has a reference seat; a plurality of reference modules each being removably seated in the reference seat of the adaptor socket so as to be electrically coupled to the test board through the adaptor socket; wherein each of the plurality of reference modules comprises a base substrate with a set of test pads corresponding to a target semiconductor component of the plurality of semiconductor components of the semiconductor package, and a set of reference semiconductor components mounted on the base substrate in a layout as all non-target semiconductor components of the plurality of semiconductor components of the semiconductor package; and a test socket disposed on the adaptor socket, wherein the test socket comprises: a socket body having a test seat for seating the semiconductor package, and defining together with the adaptor socket a lower cavity below the test seat and for accommodating one of the plurality of reference modules, such that the set of test pads of the reference module seated in the reference seat are vertically aligned with the set of conductive pads of the target semiconductor component when the semiconductor package is seated in the test seat; and contact pins vertically extending through the socket body between the test seat and the lower cavity and movable vertically relative to the socket body, wherein when the semiconductor package is under test, the contact pins are pressed by the semiconductor package against the reference module seated in the reference seat to set up an electrical connection between the set of conductive pads of the target semiconductor component and the set of test pads of the reference module seated in the reference seat.

It is to be understood that both the foregoing general description and the following detailed description are exemplary and explanatory only, and are not restrictive of the invention. Further, the accompanying drawings, which are incorporated in and constitute a part of this specification, illustrate embodiments of the invention and together with the description, serve to explain the principles of the invention.

### BRIEF DESCRIPTION OF DRAWINGS

The drawings referenced herein form a part of the specification. Features shown in the drawing illustrate only some embodiments of the application, and not of all embodiments of the application, unless the detailed description explicitly indicates otherwise, and readers of the specification should not make implications to the contrary.

FIG. 1 illustrates an apparatus for testing a semiconductor package.

FIGS. 2A and 2B illustrate an apparatus for testing a semiconductor package according to an embodiment of the present application.

FIGS. 3A to 3C illustrate respective layouts of a semiconductor package and two reference modules according to an embodiment of the present application.

FIGS. 4A to 4H illustrates a method for testing a semiconductor package according to an embodiment of the present application.

The same reference numbers will be used throughout the drawings to refer to the same or like parts.

### DETAILED DESCRIPTION OF THE INVENTION

The following detailed description of exemplary embodiments of the application refers to the accompanying drawings that form a part of the description. The drawings illustrate specific exemplary embodiments in which the application may be practiced. The detailed description, including the drawings, describes these embodiments in sufficient detail to enable those skilled in the art to practice the application. Those skilled in the art may further utilize other embodiments of the application, and make logical, mechanical, and other changes without departing from the spirit or scope of the application. Readers of the following detailed description should, therefore, not interpret the description in a limiting sense, and only the appended claims define the scope of the embodiment of the application.

In this application, the use of the singular includes the plural unless specifically stated otherwise. In this application, the use of “or” means “and/or” unless stated otherwise. Furthermore, the use of the term “including” as well as other forms such as “includes” and “included” is not limiting. In addition, terms such as “element” or “component” encompass both elements and components including one unit, and elements and components that include more than one subunit, unless specifically stated otherwise. Additionally, the section headings used herein are for organizational purposes only, and are not to be construed as limiting the subject matter described.

As used herein, spatially relative terms, such as “beneath”, “below”, “above”, “over”, “on”, “upper”, “lower”, “left”, “right”, “vertical”, “horizontal”, “side” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The device may be otherwise oriented (rotated 90 degrees or at other orientations) and the spatially relative descriptors used herein may likewise be interpreted accordingly. It should be understood that when an element is referred to as being “connected to” or “coupled to” another element, it may be directly connected to or coupled to the other element, or intervening elements may be present.

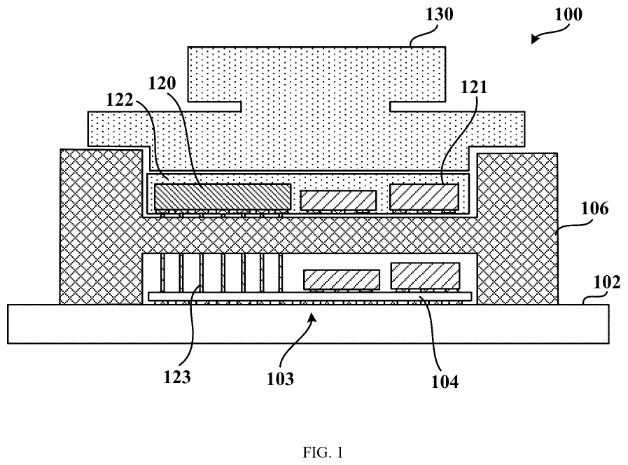

FIG. 1 illustrates an apparatus 100 for testing a semiconductor package. As shown in FIG. 1, the apparatus 100 can be used to test a semiconductor package to identify any defect of a component encapsulated within the semiconductor package, for example, a semiconductor component 120 such as a semiconductor die. The semiconductor package may further include at least one electronic component such as an electronic component 121, and a mold cap 122 encapsulating the semiconductor component 120 and the at least one electronic component. To facilitate the testing by the apparatus 100, the semiconductor component 120 has a set of conductive pads exposed from a bottom side of the mold cap 122 to provide an electrical connection between the semiconductor component 120 and external structures. Similarly, each of the at least one electronic component has an additional set of conductive pads exposed from the mold cap 122.

The apparatus 100 includes a test board 102, which serves as a base of the apparatus 100, and a reference module 103 mounted on the test board 102, which serves as an auxiliary unit when the semiconductor package is being tested. The reference module 103 may have a same size or layout as that of the semiconductor package under test, except that it does not include the semiconductor component 120. In this way, the reference module 103 can simulate the operation of the semiconductor package under test, when the semiconductor element 120 is electrically coupled to the reference module 103 through a set of contact pins 123. A test socket 106 can be used to accommodate together with the test board 102 the semiconductor package under test and the reference module 103 at two layers. The test socket 106 can vertically align the reference module 103 and the conductive pads of the semiconductor component via the contact pins 123, and set up an electrical connection between them when the semiconductor package is pressed by a lid 130 topmost of the entire apparatus 100. As such, signals can be transmitted between the test board 102 and the semiconductor component 120 to realize and verify the functions of the semiconductor component 120.

Although the apparatus 100 can test the semiconductor component 120 using the reference module 103, more test boards with corresponding reference modules mounted thereon are needed if the other electronic components such as the electronic component 121 in the semiconductor package need to be tested as well. Furthermore, more different test sockets are needed for the testing of the other electronic components because they are positioned differently in the semiconductor package from the semiconductor component 120 and may have different layouts of conductive pads. Fabricating and assembling the test boards and reference modules may take a lot of time and incur significant costs. Therefore, a new apparatus is desired, especially for testing semiconductor packages with two or more semiconductor components.

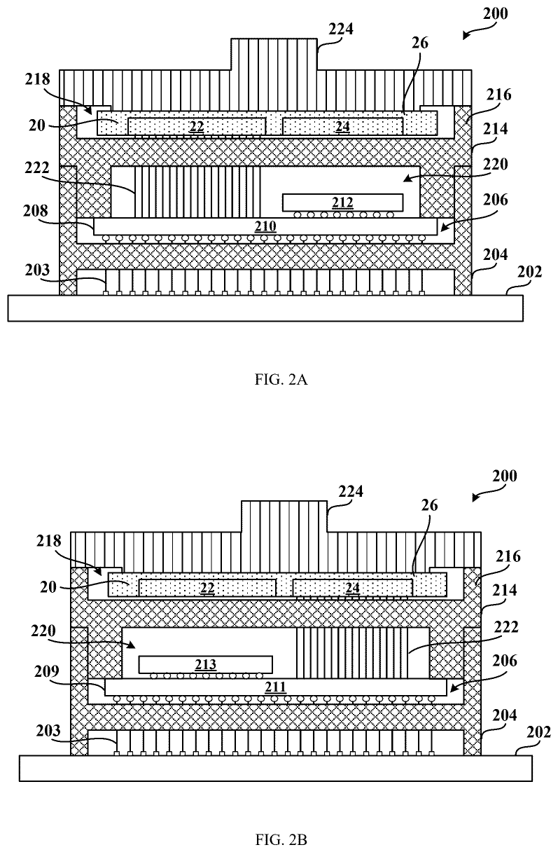

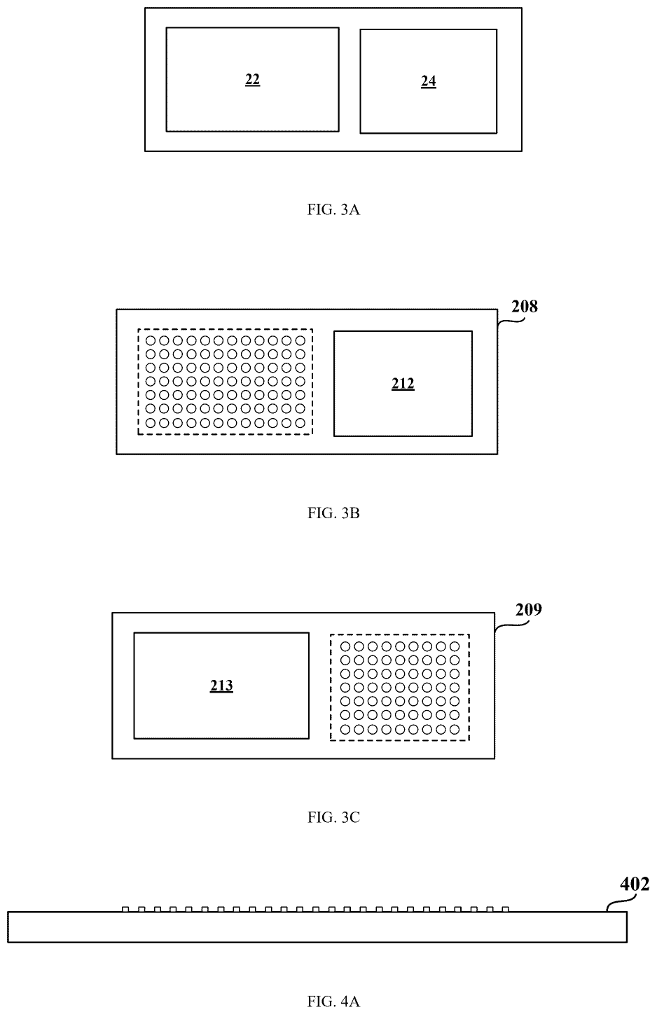

FIGS. 2A and 2B illustrate an apparatus 200 for testing a semiconductor package 20 according to an embodiment of the present application. In the embodiment, the semiconductor package 20 includes a first semiconductor component 22 and a second semiconductor component 24 which are both encapsulated within the semiconductor package 20 by a mold cap 26. For example, the semiconductor components 22 and 24 may be two semiconductor dices. The semiconductor package 20 may have a layout as shown in FIG. 3A. The first and second semiconductor components 22 and 24 may operate together as an integrated electronic system in practical applications. In order to facilitate testing of the semiconductor components 22 and 24, respective sets of conductive pads of the two semiconductor components 22 and 24 are both exposed from a bottom side of the mold cap 26 to provide respective electrical connections between the two semiconductor components 22 and 24 and external structures or components. In this way, when the first semiconductor component 22 is being tested by the apparatus 200 in a configuration shown in FIG. 2A, the exposed conductive pads of the first semiconductor component 22 can be electrically coupled to the apparatus 200; and when the second semiconductor component 24 is being tested by the apparatus 200 in another configuration shown in FIG. 2B, the exposed conductive pads of the second semiconductor component 24 can be electrically coupled to the apparatus 200. In some embodiments, the semiconductor package 20 may be pre-packaged on a package substrate which may be removed to expose the conductive pads of the first and second semiconductor components 22 and 24, and in some other embodiments, the semiconductor package 20 may be formed using a substrate-free fabrication process. The connection of the semiconductor package 20 with the apparatus 200 will be elaborated below with more details.

It can be appreciated that the semiconductor package 20 may be a package of a plurality of semiconductor packages which may have the same composition, layout, structure and functionalities. For example, the plurality of semiconductor packages may be fabricated in a same batch. All the testing may be performed on the package which is selected as a representative of the semiconductor packages. In some alternative embodiments, two packages may be selected from a plurality of semiconductor packages and used for the testing, because it is expected that the two selected packages should have substantially the same composition and performance. Slight modifications may be made to the selected packages, to have one of them include an exposed first semiconductor component and the other one include an exposed second semiconductor component. As such, the exposed semiconductor components can be tested respectively. Furthermore, in some other embodiments where three or more semiconductor components may be integrated within a single package, all of which need to be tested, one, two or more substantially identical semiconductor packages can be selected, while each of the semiconductor packages may have a portion or all of the semiconductor components exposed for testing.

Still referring to FIGS. 2A and 2B, as aforementioned, the apparatus 200 may be operated in two different configurations to test the first and second semiconductor components 22 and 24 of the semiconductor package 20, respectively. Some of the configurations of the apparatus 200 are the same or similar. Thus, the operation of the apparatus 200 will be described exemplarily with reference to the first configuration shown in FIG. 2A, and a similar operation may be performed with the apparatus 200 when it is operating in the second configuration shown in FIG. 2B.

As shown in FIG. 2A, the apparatus 200 includes a test board 202, which serves as a base of the apparatus 200 where various other components and the semiconductor package 20 under test are placed. The test board 202 may have a plurality of conductive pads (not shown) on its front surface, which may be coupled with a signal generator via various connection means (not shown), for example, traces, plugs or redistribution structures (RDSs) within the test board 202. Moreover, the signal generator can generate various test signals and test patterns for testing the semiconductor package 20.

An adaptor socket 204 is disposed on and electrically coupled to the test board 202, for example, through a set of contact pins 203 or similar connection structures. In some embodiments, the contact pins 203 may include pogo pins. In particular, each pogo pin includes a pipe-shaped pin body, a metallic top contactor coupled to a top end of the pin body, a metallic bottom contactor coupled to a bottom end of the pin body, and a compressible coil spring disposed inside the pin body. The compressible coil spring can be in contact with the top contactor at its top end, and with the bottom contactor at its bottom end. In some other embodiments, the contact pins 203 may include other types of elastic connectors, such as elastic conductive pillars. As such, when the adaptor socket 204 is placed on the test board 202 and preferably when an external force is applied onto the adaptor socket 204, the pogo pins may be pressed against the test board 202 to set up an electrical connection between the test socket 202 and the adaptor socket 204. Furthermore, the elastic connectors such as pogo pins allow for removal of the adaptor socket 204 from the test board 202, for example, when another adaptor socket with a different layout (e.g., patterns of conductive pads) needs to be tested or when the adaptor socket 204 has a failure. In other words, the test board 202 may be reused for different semiconductor packages under test, which reduces the testing cost. In the embodiment shown in FIG. 2A, the adaptor socket 204 has an H-shaped holder structure, which can accommodate the contact pins 203 within a cavity at its lower portion and provide a reference seat 206 at its upper portion. The set of contact pins 203 can be exposed from a front surface of the adaptor socket 204, and be electrically coupled to the set of conductive pads on the front surface of the test board 202.

Furthermore, the apparatus 200 may include a first reference module 208 which is removably mounted on the adaptor socket 204, or particularly removably seated in the reference seat 206. The first reference module 208 serves as an auxiliary unit when the first semiconductor component 22 of the semiconductor package 20 is under test, or particularly replacing the other components in the semiconductor package 20 to mimic the semiconductor package 20 under test as if the first semiconductor component 22 is operating in the circuit system of the semiconductor package 20.

The first reference module 208 may include a base substrate 210 with solder bumps or similar structures formed on its back surface, thereby allowing the first reference module 208 to be electrically connected with the set of contact pins 203 exposed from the front surface of the adaptor socket 204. It can be appreciated that the solder bumps of the first reference module 208 may have a layout substantially the same or similar as that of the set of contact pins 203 of the adaptor socket 204 to realize pin-to-pin connections.

In some embodiments, the first reference module 208 may have a same size or layout as that of the semiconductor package 20. In particular, the base substrate 210 has a first set of test pads (as is shown in FIG. 3B) on its front surface for providing an electrical connection between the first reference module 208 and external structures. The first set of test pads are exposed from the base substrate 210 without components formed thereon. It can be appreciated that the first set of test pads may be exposed portions of interconnect wires formed within the base substrate 210. A set of conductive pads may be formed on a back surface of the base substrate 210. The test pads and the bottom conductive pads may be electrically connected with each other through the interconnect wires formed within the base substrate 210, for example. Furthermore, the first reference module 208 further includes a second reference semiconductor component 212 mounted on the base substrate 210 in a layout the same as the second semiconductor component 24 of the semiconductor package 20 under test. As the second reference semiconductor component 212 has a same composition, structure, functionality and layout as the second semiconductor component 24 of the semiconductor package 20, it can simulate the operation of the second semiconductor component 24. When the first reference module 208 is seated within the reference seat 206, the conductive pads on the back surface of the base substrate 210 can be in contact with the set of contact pins 203 exposed from the front surface of the adaptor socket 204, thereby establishing an electrical connection between the first reference module 208 and the test board 202 through the adaptor socket 204.

Although it is described above that the contact pins 203 may have a pattern and can move vertically relative to the body of the adaptor socket 204, it is not required that the contact pins 203 can only match one pattern of conductive pads of a reference module. In some examples, the number of the contact pins 203 may be greater than the conductive pads on the bottom surface of the reference module, i.e., there may be excessive contact pins. In some other examples, the contact pins 203 may have a higher density than that of the conductive pads of the reference module(s) that can be seated in the reference seat. In this way, the contact pins 203 may be compatible with multiple pad patterns and thus multiple types of reference modules.

With continued reference to FIG. 2A, the apparatus 200 further includes a first test socket 214, which is disposed on the adaptor socket 204 and assembled together with it, e.g., through a fastener assembly. The fastener assembly can be disposed between the adaptor socket 204 and the test socket 214, and used for assembling the adaptor socket 204 with the test socket 214 through mechanical means or magnetic means. The first test socket 214 can be used to receive the semiconductor package 20, and to set up an electrical connection between the semiconductor package 20 and the first reference module 208 on the adaptor socket 204.

In particular, the first test socket 214 includes a socket body 216, which has a test seat 218 for seating the semiconductor package 20. Furthermore, the socket body 216 also defines together with the adaptor socket 204 a lower cavity 220 below the test seat 218, which is used to accommodate the first reference module 208 or another reference module as will be described below. The first test socket 214 further includes contact pins 222, which vertically extend through the socket body 216 between the test seat 218 and the lower cavity 220. The contact pins 222 can be movable vertically relative to the socket body 216. In particular, the socket body 216 may include slots extending therethrough each receiving one of the contact pins 222. The socket body 216 can fix and support the contact pins 222 to protect them from deformation and external physical impact, which improves an alignment accuracy between the set of test pads of the first reference module 208 and the set of conductive pads of the first semiconductor component 22, respectively. In some embodiments, the slots may be distributed horizontally across a portion of the socket body 216. Before testing the first semiconductor component 22, the contact pins 222 can be inserted through a respective set of slots which are aligned with the conductive pads of the first semiconductor component 22. As such, the socket body 216 can be reused when testing another component within the semiconductor package 20. In some embodiments, the contact pins 222 may include pogo pins or similar elastic connection structures. It can be appreciated that in some embodiments the contact pins 222 may be integrated with the socket body 216 and cannot be removed from the socket body 216. In that case, if another semiconductor component such as the second semiconductor component 24 needs to be tested, another test socket can be used with the adaptor socket 204 and the test board 202, instead of the test socket 214.

In the embodiment shown in FIG. 2A, the test socket 214 further includes a step structure at its outer wall. The step structure can be engaged with the adaptor socket 204 when it is placed on the adaptor socket 204. Furthermore, depending on a height of the first reference module 208, the step structure may also be engaged with the front surface of the base substrate 210 of the first reference module 208. In operation, when a force is applied to the test socket 214 from its topside, the test socket 214 may deliver the force to the first reference module 208 and optionally further to the adaptor socket 204 (if the first reference module 208 is pushed downward to some extent), to press them against the test board 202 to ensure the electrical connection between the semiconductor package 20 and the test board 202.

In some embodiments, the apparatus 200 may further include a socket lid 224 disposed above the socket body 216 and the semiconductor package 20. The socket lid 224 may be used for pushing the semiconductor package 20 towards the test board 202, thereby providing an external force applied to the semiconductor package 20, which can be delivered to the first test socket 214, to the first reference module 208 and to the adaptor socket 204. When the semiconductor package 20 is being tested, or particularly the first semiconductor component 22 is being tested, the contact pins 222 can be pressed by the semiconductor package 20 against the first reference module 208, and the contact pins 203 of the adaptor socket 204 can be pressed by the first reference module 208, to set up an electrical connection from the first semiconductor component 22 to the test board 202. In this way, the first semiconductor component 22 can be tested by the test board 202 as if it is operating in the circuit system of the semiconductor package 20.

In some embodiments, apart from the vertical alignment between the test pads of the first reference module 208 and the conductive pads of the first semiconductor component 22, the second semiconductor component 24 within the semiconductor package 20 is also vertically aligned with the second reference electronic component 212 mounted on the base substrate 210. To be more specific, a projection of the second semiconductor component 24 onto the base substrate 210 may totally overlap with a projection of the reference semiconductor component 212 onto the base substrate 210. In other words, the reference semiconductor component 210 has the same composition, structure, functionality and layout as the second semiconductor component 24, acting as its duplicate.

The apparatus 200 may offer multiple advantages when testing semiconductor packages. Firstly, the apparatus 200 creates a complete electronic module or system including the first semiconductor component 22 and the reference semiconductor component 212 to mimic the semiconductor package 20 under test. The testing process does not need to break the semiconductor package 20 to get access to the semiconductor component 22 encapsulated within the mold cap 26. Secondly, since the first reference module 208 may have a same size and layout as that of the semiconductor package 20, connection means, e.g., traces, plugs or redistribution structures (RDSs) originally designed for providing signals for the semiconductor package 20 may provide optimal signals for the first reference module 208 when testing the first semiconductor component 22 within the semiconductor package 20. Thirdly and most importantly, when the apparatus 200 is used to test semiconductor packages with two or more semiconductor components, such as the semiconductor package 20 with two semiconductor components 22 and 24, modifications but not an entire replacement can be made to the configuration of the apparatus 200 to test all the semiconductor components of such semiconductor packages.

FIG. 2B illustrates that the apparatus 200 shown in FIG. 2A operates in the second configuration to test the second semiconductor component 24 of the semiconductor package 20. The second configuration is similar to the first configuration shown in FIG. 2A, with some modifications as elaborated below.

As shown in FIG. 2B, when the semiconductor package 20 is seated in the test seat 218 for testing the second semiconductor component 24, a set of conductive pads of the second semiconductor component 24 may be exposed from the back surface of the semiconductor package 20, or particularly from the back surface of the mold cap 26. Accordingly, the contact pins 222 may be placed under the second semiconductor component 24, instead of under the first semiconductor component 22 when the second semiconductor component 24 is being tested. In particular, the contact pins 222 may be aligned with the exposed conductive pads of the second semiconductor component 24 to be electrically coupled to the semiconductor component 24. Furthermore, a second reference module 209 which may have a “complementary” layout as the first reference module 208 shown in FIG. 2A may be placed on the adaptor socket 204 and seated within the reference seat 206.

Similar as the first reference module 208, the second reference module 209 may have a same size or layout as that of the semiconductor package 20. In particular, a base substrate 211 of the second reference module 209 has a second set of test pads (as is shown in FIG. 3C) on its front surface for providing an electrical connection between the second reference module 209 and external structures. The second set of test pads are exposed from the base substrate 211 without components formed thereon. The second reference module 209 further includes a first reference semiconductor component 213 mounted on the base substrate 211 in a layout the same as the first semiconductor component 22 of the semiconductor package 20 under test. As the first reference semiconductor component 213 has a same composition, structure, functionality and layout as the first semiconductor component 22, it can simulate the operation of the first semiconductor component 22. When the second reference module 209 is seated within the reference seat 206, the conductive pads on the back surface of the base substrate 211 can be in contact with the set of contact pins exposed from the front surface of the adaptor socket 204, thereby establishing an electrical connection between the second reference module 209 and the test board 202 through the adaptor socket 204.

As aforementioned, the second set of test pads are exposed from the base substrate 211, which are aligned with the contact pins 222 and the exposed bottom conductive pads of the second semiconductor component 24. As such, when the socket lid 224 pushes the semiconductor package 20 towards the test socket 202, an electrical connection from the second semiconductor component 24 to the test board 202 through the test socket 214, the second reference module 209 and the adaptor socket 204 can be established. In this way, the second semiconductor component 24 can be tested by the test board 202 as if it is operating in the circuit system of the semiconductor package 20.

As can be seen from FIGS. 2A and 2B, at least a portion of the apparatus 200 can be used during the testing of both the first semiconductor component 22 and the second semiconductor component 24, which reduces the testing cost and makes the testing convenient in operation. For example, in some embodiments, at least the test board 202 and the adaptor socket 204 can be used twice, and in some preferred embodiments, at least the test socket 214 can be used twice. In other words, only two or more reference modules need to be prepared for the respective testing of the first and second semiconductor components or other semiconductor components of the semiconductor package 20. In some alternative embodiments, the test socket 214 may have integrated contact pins 222 and thus two test sockets with two different sets of contact pins (e.g., one set corresponding to the first semiconductor component 22 and the other set corresponding to the second semiconductor component 24) may be used.

It can be appreciated that the apparatus 200 shown in FIGS. 2A and 2B is used to test a semiconductor package with two semiconductor components, and accordingly two reference modules are used. In some other embodiments where three or more semiconductor components are integrated in a single semiconductor package and need to be tested, three or more reference modules may be prepared and used for the testing. One of the three or more semiconductor components which is under test can be referred to as a target semiconductor component, and the other semiconductor components of the three or more semiconductor components which are not under test can be referred to as non-target semiconductor components. Accordingly, each of the reference modules may include a set of test pads corresponding to a target semiconductor component under test, and a set of reference semiconductor components corresponding to all the other semiconductor components can be referred to as non-target semiconductor components. Also, it can be appreciated that the target semiconductor components corresponding to the respective reference modules are different from each other.

A process for forming a reference module is as follows. First, a pre-mold semiconductor package may be provided. The pre-molded semiconductor package includes a base substrate, a first semiconductor component and a second semiconductor component mounted on the base substrate, and a mold cap or molding layer encapsulating the semiconductor components. In particular, the first semiconductor component is mounted on a first set of test pads (not shown) on a front surface of the base substrate, and the second component is mounted on a second set of test pads (not shown) on the front surface of the base substrate. Furthermore, the base substrate further includes additional conductive pads on a back surface of the base substrate. The first and second sets of test pads and the back conductive pads may be electrically connected together through interconnect wires formed within the base substrate, for example. Next, the molding layer and the first semiconductor component may be removed from the base substrate to expose the first set of test pads and the second semiconductor component, thereby forming the first reference module. Alternatively, the molding layer and the second semiconductor component may be removed from the base substrate to expose the second set of test pads and the first semiconductor component, thereby forming the second reference module.

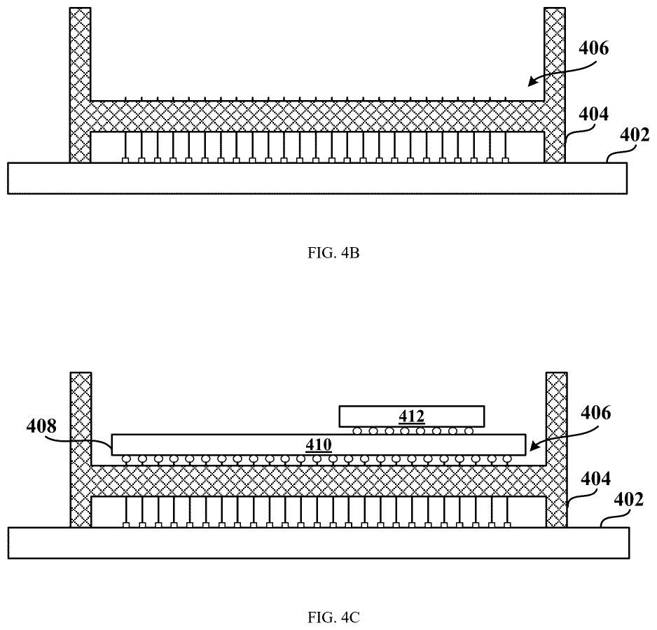

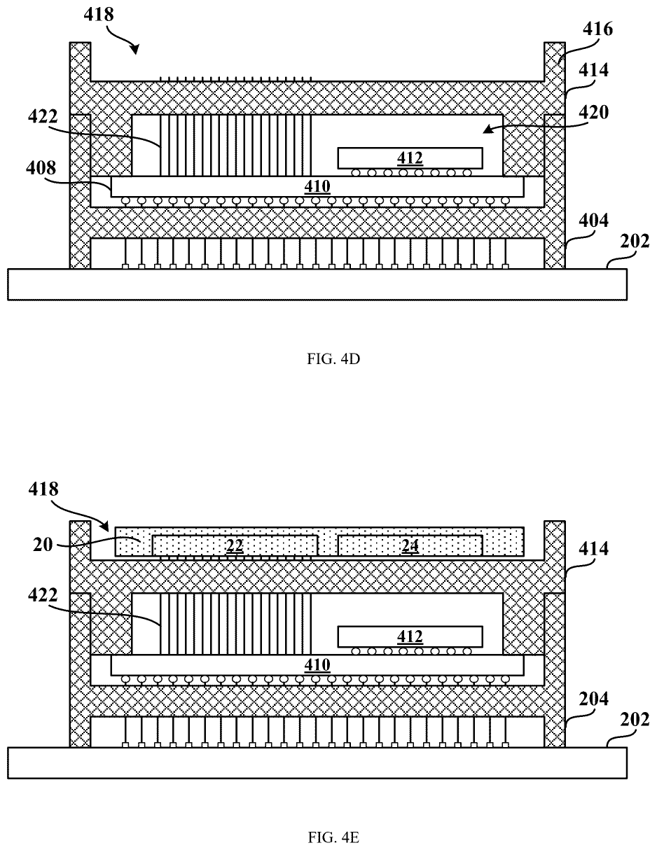

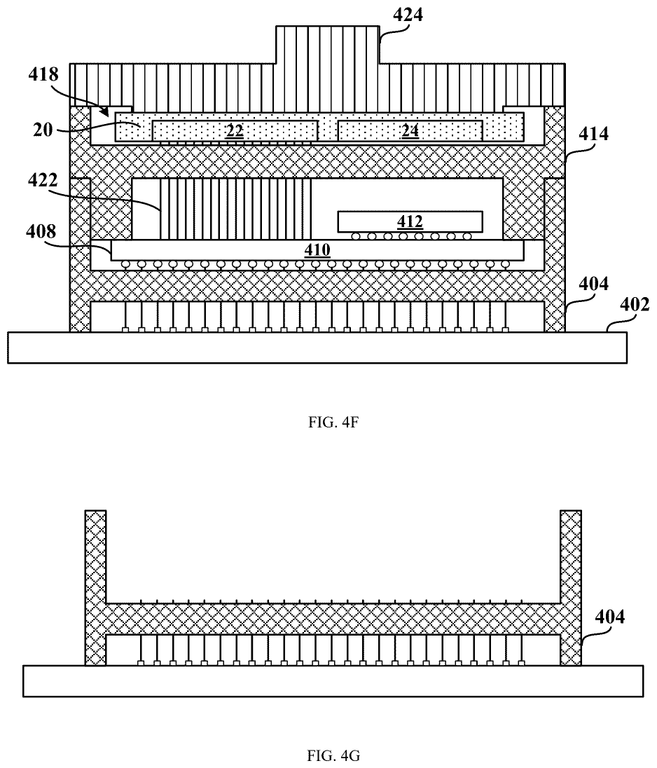

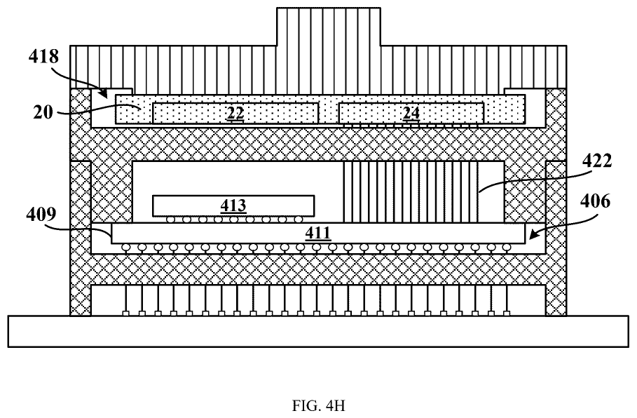

FIGS. 4A to 4H illustrate various steps of a method for testing a semiconductor package according to an embodiment of the present application. In some embodiments, the method may be implemented by the apparatus 200 shown in FIGS. 2A and 2B. The semiconductor package 20 under test may have a layout shown in FIG. 3A, which has at least a first semiconductor component 22 and a second semiconductor component 24, and a mold cap encapsulating the first and second semiconductor components 22 and 24. The first semiconductor component 22 has a first set of conductive pads exposed from the mold cap, and the second semiconductor component 24 has a second set of conductive pads exposed from the mold cap. For example, the sets of conductive pads may be both exposed from a back surface of the mold cap.

Furthermore, various reference modules may be used in the testing process. For example, a first reference module such as the first reference module 208 shown in FIG. 3B and a second reference module such as the second reference module 209 shown in FIG. 3C can be used. The first reference module 208 may include a first base substrate with a first set of test pads and a second reference semiconductor component 212 mounted on the first base substrate in a layout as the second semiconductor component of the semiconductor package. Similarly, the second reference module may include a second base substrate with a second set of test pads and a first reference semiconductor component 213 mounted on the second base substrate in a layout as the first semiconductor component of the semiconductor package. Each of the reference modules can be removably seated in the reference seat of the adaptor socket so as to be electrically coupled to the test board through the adaptor socket.

As shown in FIG. 4A, a test board 402 may be provided, for example, placed on a platform or table. The test board 402 may have a plurality of contact pads on its front surface, which may be coupled with a signal generator via various connection means (not shown), for example, traces, plugs or redistribution structures (RDSs) within the test board 402. Moreover, the signal generator can generate various test signals and test patterns for testing the semiconductor package.

Next, as shown in FIG. 4B, an adaptor socket 404 having a reference seat 406 is disposed on the test board 402. The adaptor socket 406 can be electrically coupled to the test board 402, for example, through a set of contact pins or similar connection structures that extend from the reference seat 406 to the test board 402. The set of contact pins may be aligned with the set of conductive pads of the test board 402, and can move vertically between a first position where they are in contact with the set of conductive pads and a second position where they are not in contact with the set of conductive pads. In some embodiments, the contact pins may include pogo pins.

As aforementioned, a set of contact pads can be formed on the test board 402 and exposed from a front surface of the test board 402. The set of contact pads can be electrically coupled to the set of contact pins in the lower cavity of the adaptor socket 404. Next, as shown in FIG. 4C, the first reference module 408 may be placed in the reference seat 406 and electrically coupled to the set of contact pins therein. In this way, the first reference module 408 can be electrically coupled to the test board 402 via the adaptor socket 404. The first reference module 404 has a first base substrate 410, with a portion of its front surface covered by a second reference semiconductor component 412 and the remaining portion exposed where a first set of test pads can be formed and exposed.

Next, as shown in FIG. 4D, a test socket 414 is placed on the adaptor socket 404. The test socket 414 includes a socket body 416 having a test seat 418. The socket body 416 defines together with the adaptor socket 404 a lower cavity 420 below the test seat 418. Also, the test socket 414 includes contact pins 422, which vertically extend through the socket body 416 between the test seat 418 and the lower cavity 420 and are movable relative to the socket body 416. The first reference module 408 is thus accommodated within the lower cavity 420.

Next, as shown in FIG. 4E, the semiconductor package 20 is placed in the test seat 418 of the test socket 414. In particular, the first semiconductor component 22 of the semiconductor package 20 may be tested. Accordingly, the first set of conductive pads of the first semiconductor component 22 which are exposed from the back surface of the semiconductor package 20 can be aligned with the contact pins 422. Furthermore, the second semiconductor component 24 of the semiconductor package 20 may be “virtually” aligned with the second reference semiconductor component 412 without any electrical connection therebetween.

Next, as shown in FIG. 4F, the semiconductor package 20 may be pressed towards the test socket 414, for example, by a socket lid 424, to press the contact pins 422 against the first reference module 408 to set up an electrical connection between the first set of conductive pads of the first semiconductor component 20 and the first set of test pads of the first reference module 408. Furthermore, since the first reference module 408 is electrically coupled to the test board 402 through the adaptor socket 404, an electrical connection between the first semiconductor component 22 and the test board 402 can be set up through the test socket 414, the first reference module 408 and the adaptor socket 404, and thus the first semiconductor component 22 can be tested by the test board 402 as if it is operating in the semiconductor package 20.

After the testing of the first semiconductor component 22 is completed, the semiconductor package, the test socket and the first reference module can be removed from the adaptor socket 404, as is shown in FIG. 4G. An assembling or preparation process that are similar as those steps shown in FIGS. 4C to 4F can be implemented, differing only in that the second reference module 409 is placed in the reference seat 406 and that the contact pins 422 are aligned with the exposed second set of test pads on the second base substrate 411. In some embodiments, the change in the position of the contact pins 422 can be implemented using the same test socket, while in some other embodiments, a different test socket may be used with the differently positioned set of contact pins. As such, when the semiconductor package 20 is placed in the test seat 418, the second semiconductor component 24 can be tested using the apparatus, as is shown in FIG. 4H.

The discussion herein includes numerous illustrative figures that show various portions of an apparatus for testing a semiconductor package and a method for testing a semiconductor package. For illustrative clarity, such figures do not show all aspects of each exemplary method. Any of the example methods provided herein may share any or all characteristics with any or all other methods provided herein.

Various embodiments have been described herein with reference to the accompanying drawings. It will, however, be evident that various modifications and changes may be made thereto, and additional embodiments may be implemented, without departing from the broader scope of the invention as set forth in the claims that follow. Further, other embodiments will be apparent to those skilled in the art from consideration of the specification and practice of one or more embodiments of the invention disclosed herein. It is intended, therefore, that this application and the examples herein be considered as exemplary only, with a true scope and spirit of the invention being indicated by the following listing of exemplary claims.

1. An apparatus for testing a semiconductor package, wherein the semiconductor package comprises at least a first semiconductor component and a second semiconductor component and a mold cap encapsulating the first and second semiconductor components, wherein the first semiconductor component has a first set of conductive pads exposed from the mold cap, and the second semiconductor component has a second set of conductive pads exposed from the mold cap, and wherein the apparatus comprises:
a test board;
an adaptor socket disposed on and electrically coupled to the test board, wherein the adaptor socket has a reference seat;
a first reference module and a second reference module each being removably seated in the reference seat of the adaptor socket so as to be electrically coupled to the test board through the adaptor socket, wherein the first reference module comprises a first base substrate with a first set of test pads and a second reference semiconductor component mounted on the first base substrate in a layout as the second semiconductor component of the semiconductor package, and the second reference module comprises a second base substrate with a second set of test pads and a first reference semiconductor component mounted on the second base substrate in a layout as the first semiconductor component of the semiconductor package; and
a test socket disposed on the adaptor socket, wherein the test socket comprises:
a socket body having a test seat for seating the semiconductor package, and defining together with the adaptor socket a lower cavity below the test seat and for accommodating the first reference module or the second reference module, such that the first set of test pads of the first reference module are vertically aligned with the first set of conductive pads of the first semiconductor component or the second set of test pads of the second reference module are vertically aligned with the second set of conductive pads of the second semiconductor component when the semiconductor package is seated in the test seat; and
contact pins vertically extending through the socket body between the test seat and the lower cavity and movable vertically relative to the socket body, wherein when the semiconductor package is under test, the contact pins are pressed by the semiconductor package against the first reference module or the second reference module to set up an electrical connection between the first set of conductive pads of the first semiconductor component and the first set of test pads of the first reference module or between the second set of conductive pads of the second semiconductor component and the second set of test pads of the second reference module.

2. The apparatus of claim 1, further comprising:
a socket lid disposed above the test socket and the semiconductor package, wherein the socket lid is configured for pushing the semiconductor package towards the test socket.

3. The apparatus of claim 2, wherein the contact pins comprise pogo pins.

4. The apparatus of claim 1, further comprising:
a fastener assembly disposed between the adaptor socket and the test socket, and configured for assembling the adaptor socket with the test socket.

5. The apparatus of claim 1, wherein the adaptor socket is electrically coupled to the test board through contact pins.

6. The apparatus of claim 1, wherein the test socket comprises a step structure configured for pressing adaptor socket and the first or second reference module when it is placed on the adaptor socket.

7. A method for testing a semiconductor package, wherein the semiconductor package comprises at least a first semiconductor component and a second semiconductor component and a mold cap encapsulating the first and second semiconductor components, wherein the first semiconductor component has a first set of conductive pads exposed from the mold cap, and the second semiconductor component has a second set of conductive pads exposed from the mold cap; and wherein the method comprises:
providing a first reference module and a second reference module, wherein the first reference module comprises a first base substrate with a first set of test pads and a second reference semiconductor component mounted on the first base substrate in a layout as the second semiconductor component of the semiconductor package, and the second reference module comprises a second base substrate with a second set of test pads and a first reference semiconductor component mounted on the second base substrate in a layout as the first semiconductor component of the semiconductor package;
providing a test board with an adaptor socket disposed thereon, wherein the adaptor socket is electrically coupled to the test board and has a reference seat;
placing the first reference module in the reference seat of the adaptor socket such that the first reference module is electrically coupled to the test board via the adaptor socket;
placing a test socket on the adaptor socket, wherein the test socket comprises a socket body having a test seat and defining together with the adaptor socket a lower cavity below the test seat, and contact pins vertically extending through the socket body between test seat and the lower cavity and movable relative to the socket body, and wherein the first reference module is accommodated within the lower cavity;
placing the semiconductor package in the test seat of the test socket to set up an electrical connection between the first set of conductive pads of the first semiconductor component and the first set of test pads of the first reference module;
removing the semiconductor package, the test socket and the first reference module from the adaptor socket;
placing the second reference module in the reference seat of the adaptor socket such that the second reference module is electrically coupled to the test board via the adaptor socket;
placing the test socket on the adaptor socket to accommodate the second reference module in the lower cavity; and
placing the semiconductor package in the test seat of the test socket to set up an electrical connection between the second set of conductive pads of the second semiconductor component and the second set of test pads of the second reference module.

8. The method of claim 7, wherein placing the semiconductor package in the test seat of the test socket further comprises:
pushing the semiconductor package towards the test socket via a socket lid disposed above the socket body and the semiconductor package.

9. The method of claim 7, wherein the contact pins comprise pogo pins.

10. An apparatus for testing a semiconductor package, wherein the semiconductor package comprises a plurality of semiconductor components and a mold cap encapsulating the plurality of semiconductor components, wherein each of the plurality of semiconductor components has a set of conductive pads exposed from the mold cap, and wherein the apparatus comprises:
a test board;
an adaptor socket disposed on and electrically coupled to the test board, wherein the adaptor socket has a reference seat;
a plurality of reference modules each being removably seated in the reference seat of the adaptor socket so as to be electrically coupled to the test board through the adaptor socket; wherein each of the plurality of reference modules comprises a base substrate with a set of test pads corresponding to a target semiconductor component of the plurality of semiconductor components of the semiconductor package, and a set of reference semiconductor components mounted on the base substrate in a layout as all non-target semiconductor components of the plurality of semiconductor components of the semiconductor package; and
a test socket disposed on the adaptor socket, wherein the test socket comprises:
a socket body having a test seat for seating the semiconductor package, and defining together with the adaptor socket a lower cavity below the test seat and for accommodating one of the plurality of reference modules, such that the set of test pads of the reference module seated in the reference seat are vertically aligned with the set of conductive pads of the target semiconductor component when the semiconductor package is seated in the test seat; and
contact pins vertically extending through the socket body between the test seat and the lower cavity and movable vertically relative to the socket body, wherein when the semiconductor package is under test, the contact pins are pressed by the semiconductor package against the reference module seated in the reference seat to set up an electrical connection between the set of conductive pads of the target semiconductor component and the set of test pads of the reference module seated in the reference seat.

11. The apparatus of claim 10, further comprising:
a socket lid disposed above the test socket and the semiconductor package, wherein the socket lid is configured for pushing the semiconductor package towards the test socket.

12. The apparatus of claim 11, wherein the contact pins comprise pogo pins.

13. The apparatus of claim 10, further comprising:
a fastener assembly disposed between the adaptor socket and the test socket, and configured for assembling the adaptor socket with the test socket.

14. The apparatus of claim 10, wherein the adaptor socket is electrically coupled to the test board through contact pins.

15. The apparatus of claim 10, wherein the test socket comprises a step structure configured for pressing adaptor socket and the reference module seated in the reference seat when it is placed on the adaptor socket.
